(19) United States
(12) Patent Application Publication
(10) Pub. No.: US 2019/0296149 A1
(43) Pub. Date: Sep. 26, 2019

(54) SEMICONDUCTOR DEVICE

(71) Applicant: DENSO CORPORATION, Kariya-city (JP)

(72) Inventors: Tsuyoshi YAMAMOTO, Kariya-city (JP); Kenta GODA, Kariya-city (JP); Shunsuke HARADA, Kariya-city (JP); Yoshiaki NAKAYAMA, Kariya-city (JP)

(21) Appl. No.: 16/439,023

(22) Filed: Jun. 12, 2019

Related U.S. Application Data
(63) Continuation of application No. PCT/JP2017/046010, filed on Dec. 21, 2017.

(30) Foreign Application Priority Data
Dec. 21, 2016 (JP) 2016-248185

(51) Int. Cl. H01L 29/78; H01L 29/06; H01L 29/10; H01L 29/40; H01L 29/739

(52) U.S. Cl. CPC H01L 29/7815; H01L 29/7813; H01L 29/7397; H01L 29/1095; H01L 29/407; H01L 29/0696

(57) ABSTRACT

In a semiconductor device, a trench is continuously connected to reach a main cell region and a sense cell region, and a shield electrode and a gate electrode layer are continuously connected to reach the main cell region and the sense cell region within the trench. The shield electrode extends to a side of the main cell region away from the sense cell region on one end side of the trench in a longitudinal direction to be electrically connected to an upper electrode. The gate electrode layer extends to a side of the main cell region away from the sense cell region on the other end side of the trench in the longitudinal direction to be electrically connected to a gate liner.

### CROSS REFERENCE TO RELATED APPLICATIONS

The present application is a continuation application of International Patent Application No. PCT/JP2017/046010 filed on Dec. 21, 2017, which designated the U.S. and claims the benefit of priority from Japanese Patent Application No. 2016-248185 filed on Dec. 21, 2016. The entire disclosures of all of the above applications are incorporated herein by reference.

### TECHNICAL FIELD

The present disclosure relates to a semiconductor device.

### BACKGROUND

In some semiconductor devices, vertical semiconductor switching elements having similar structures are provided in a main cell region and a sense cell region, each of the vertical semiconductor switching elements has a trench gate of a two-layered structure, and a current flowing through a main cell is detected by a sense cell.

### SUMMARY

The present disclosure provides a semiconductor device in which a trench is continuously connected to reach a main cell region and a sense cell region, and a shield electrode and a gate electrode layer are continuously connected to reach the main cell region and the sense cell region within the trench. The shield electrode extends to a side of the main cell region away from the sense cell region on one end side of the trench in a longitudinal direction to be electrically connected to an upper electrode. The gate electrode layer extends to a side of the main cell region away from the sense cell region on the other end side of the trench in the longitudinal direction to be electrically connected to a gate liner.

### BRIEF DESCRIPTION OF DRAWINGS

The above and other objects, features and advantages of the present disclosure will become more apparent from the following detailed description made with reference to the accompanying drawings. In the drawings:

FIG. 1 is a top layout diagram of a semiconductor device according to a first embodiment;

FIG. 2 is a cross-sectional view of the semiconductor device taken along a line II-II in FIG. 1;

FIG. 3 is a cross-sectional view of the semiconductor device taken along a line III-III in FIG. 1; and

FIG. 4 is a cross-sectional view of the semiconductor device taken along a line IV-IV in FIG. 1.

### DETAILED DESCRIPTION

First, a semiconductor device according to a related art will be described. In the semiconductor device according to the related art, vertical semiconductor switching elements having similar structures are provided in a main cell region and a sense cell region, each of the vertical semiconductor switching elements has a trench gate of a two-layered structure, and a current flowing through a main cell is detected by a sense cell.

In the two-layer structure, a shield electrode serving as a source potential is disposed in a bottom portion of a trench, and a gate electrode layer is disposed above the shield electrode in the trench. The trench is formed into a line shape having one direction as a longitudinal direction, and the trench is divided in the longitudinal direction, whereby the gate electrode layer and the shield electrode in each trench are separated between the main cell and the sense cell. In order to bring into contact with the shield electrode, the shield electrode is formed to a surface of the semiconductor substrate at a tip portion of the trench, and the shield electrode extends to the tip portion of the trench more than the gate electrode layer. In other words, a contact portion of the shield electrode of the sense cell is formed between the main cell and the sense cell.

In the above-described semiconductor device, the shield electrode of the sense cell is projected between the main cell and the sense cell, and the contact portion of the shield electrode is formed in the projected portion. Thus, there is an issue that the distance between the main cell and the sense cell becomes long, and an accuracy of current detection by the sense cell is lowered.

Specifically, it is important to shorten the distance between the main cell and the sense cell so that the current detection by the sense cell can be performed with high accuracy. When the distance between the main cell and the sense cell increases, a current spreads and flows in a planar direction of the semiconductor substrate, that is, in a horizontal direction so as to diffuse between the main cell and the sense cell. Thus, in the main cell having a large area, the current flows uniformly in the thickness direction of the semiconductor substrate, that is, in the vertical direction, without much influence of the current flow in the horizontal direction, but in the sense cell having a small area, the current does not flow uniformly in the vertical direction due to the influence of the current flow in the horizontal direction. Therefore, an accuracy in current detection by the sense cell is lowered.

Further, when the vertical semiconductor switching element such as a MOSFET is driven, a desired voltage is applied to the gate electrode layer, but a current ratio of the main cell to the sense cell when a gate voltage is applied may change without being fixed. At this time, when the accuracy in current detection by the sense cell in the case where the gate voltage is equal to the desired voltage is used as the reference accuracy, and the amount of change from the reference accuracy in the case where the gate voltage deviates from the desired voltage is calculated, the amount of change increases as the distance between the main cell and the sense cell increases. Further, the amount of change from the reference accuracy also changes depending on a use temperature of the semiconductor device, and even at the same use temperature, the amount of change from the reference accuracy increases as the distance between the main cell and the sense cell increases.

As a method for solving such an issue, a method of detecting a current flowing in a main cell by providing a shunt resistor in series with a main cell without providing the sense cell and monitoring a voltage across both ends of the shunt resistor can be considered. However, a shunt resistor causes a current loss, and the system becomes expensive, for example, due to requiring a shunt resistor with high accuracy.

A semiconductor device according to an aspect of the present disclosure includes a main cell region and a sense cell region each including a semiconductor switching element, and is configured to detect a current flowing through the semiconductor switching element in the main cell region by the semiconductor switching element in the sense cell region.

In the semiconductor device, the semiconductor switching element includes a drift layer of a first conductivity type, a channel layer of a second conductivity type disposed on the drift layer, a first impurity region of a first conductivity type disposed in a surface layer portion of the channel layer and having an impurity concentration higher than an impurity concentration of the drift layer, a trench gate structure in which a shield electrode and a gate electrode layer are stacked as a two-layer structure through a gate insulating film within a trench that reaches the drift layer from the first impurity region through the channel layer and extends in one direction as a longitudinal direction, a second impurity region of the first or second conductivity type disposed on an opposite side to the channel layer across the drift layer and has an impurity concentration higher than the impurity concentration of the drift layer, an upper electrode electrically connected to the first impurity region and the channel layer and electrically connected to the shield electrode, a gate liner electrically connected to the gate electrode layer, and a lower electrode electrically connected to the second impurity region. The trench is continuously connected to reach the main cell region and the sense cell region, and the shield electrode and the gate electrode layer are continuously connected to reach the main cell region and the sense cell region within the trench. The shield electrode extends to a side of the main cell region away from the sense cell region on one end side of the trench in the longitudinal direction to be electrically connected to the upper electrode. The gate electrode layer extends to a side of the main cell region away from the sense cell region on the other end side of the trench in the longitudinal direction to be electrically connected to the gate liner.

According to the above-described semiconductor device, there is no need to make a contact of the shield electrode between the main cell region and the sense cell region, and the main cell region and the sense cell region can be close to each other. Therefore, the current can be restricted from spreading and flowing between the main cell region and the sense cell region, and the current can flow uniformly in the vertical direction in the sense cell region as in the main cell region. Accordingly, the accuracy of the sense cell can be improved.

Embodiments of the present disclosure will be described below with reference to the drawings. In the following embodiments, the same reference numerals are assigned to parts that are the same or equivalent to each other to describe the same.

### First Embodiment

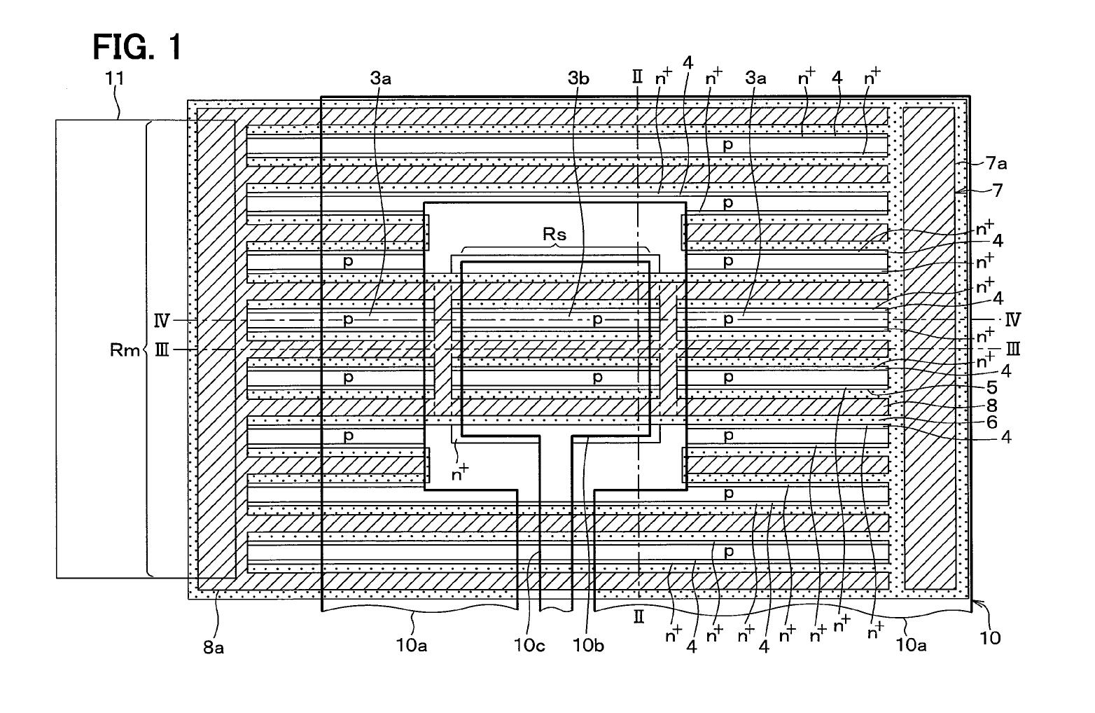

A first embodiment will be described. In the present embodiment, a description will be given of a semiconductor device in which n-channel type vertical MOSFETs having similar structure are provided in the main cell region and the sense cell region. Hereinafter, a structure of the semiconductor device according to the present embodiment will be described with reference to FIGS. 1 to 4.

As shown in FIG. 1, the semiconductor device according to the present embodiment includes a main cell region Rm and a sense cell region Rs. The main cell region Rm has a rectangular frame shape which is partially cut out, and the sense cell region Rs is disposed in the main cell region Rm and is surrounded by the main cell region Rm.

In the main cell region Rm and the sense cell region Rs, an n-channel type vertical MOSFET having similar structures is formed.

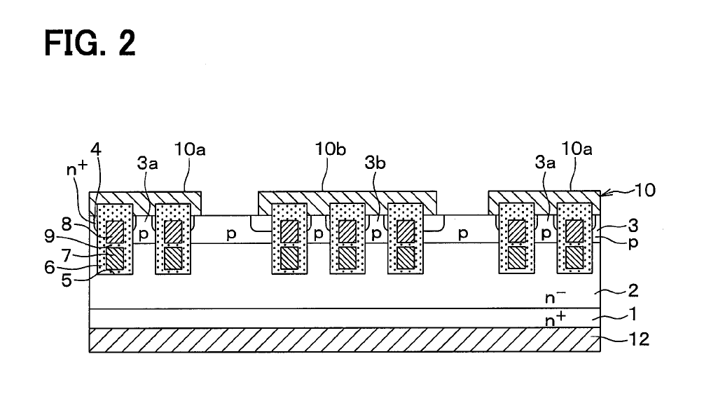

As shown in FIG. 2, the semiconductor device is formed with an n⁺-type semiconductor substrate 1 which is made of a semiconductor material such as silicon having a high impurity concentration. An n⁻-type drift layer 2 having an impurity concentration lower than the impurity concentration of the n⁺-type semiconductor substrate 1 is formed on a surface of the n⁺-type semiconductor substrate 1, and a channel p-type layer 3 having a relatively low impurity concentration is formed at a desired position of the n⁻-type drift layer 2.

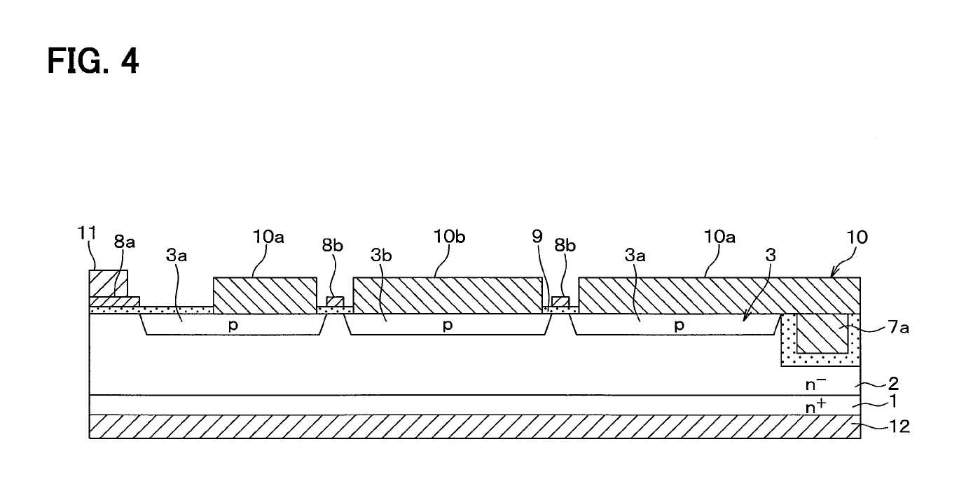

The channel p-type layer 3 is formed by ion-implanting a p-type impurity into the n⁻-type drifting layer 2. The channel p-type layer 3 is divided into a main channel layer 3a formed in the main cell region Rm and a sense channel layer 3b formed in the sense cell region Rs, and as shown in FIG. 4, the main channel layer 3a and the second channel layer 3b are separated from each other by a predetermined distance in a longitudinal direction of trench gate structures to be described later. As shown in FIG. 2, since the trench gate structure is provided between the main channel layer 3a and the sense channel layer 3b, the main channel layer 3a and the sense channel layer 3b are also separated from each other in a direction orthogonal to the longitudinal direction of the trench gate structure.

An n⁺-type impurity region 4 corresponding to a source region having an impurity concentration higher than the impurity concentration of the n⁻-type drift layer 2 is provided in a surface layer portion of the channel p-type layer 3. Trenches 5 are provided from the substrate surface to the n⁻-type drift layer 2 through the n⁺-type impurity regions 4 and the channel p-type layer 3. A gate insulating film 6 is formed so as to cover an inner wall surface of the trench 5, and a shield electrode 7 and a gate electrode layer 8 made of doped Poly-Si are stacked in the trench 5 through the gate insulating film 6 to form a two-layered structure. The shield electrode 7 is fixed to a source potential to reduce a capacitance between a gate and a drain and improve the electrical properties of the MOSFET. The gate electrode layer 8 performs a MOSFET switching operation and defines a channel in the channel p-type layer 3 on a side of the trench 5 when a gate voltage is applied.

An insulating film 9 is formed between the shield electrode 7 and the gate electrode layer 8, and the shield electrode 7 and the gate electrode layer 8 are insulated by an insulating film 9. The trench 5, the gate insulating film 6, the shield electrode 7, the gate electrode layer 8, and the insulating film 9 configure a trench gate structure. The trench gate structures are formed in a stripe shape in which the multiple trench gate structures are aligned in a left-right direction of the paper sheet of FIG. 2 with a direction perpendicular to the paper sheet of FIG. 2 as the longitudinal direction, for example.

However, no trench gate structure is provided between the main cell region Rm and the sense cell region Rs. An interval between adjacent trench gate structures between the main cell region Rm and the sense cell region Rs is wider than an interval between the adjacent trench gate structures in the main cell region Rm or the sense cell region Rs.

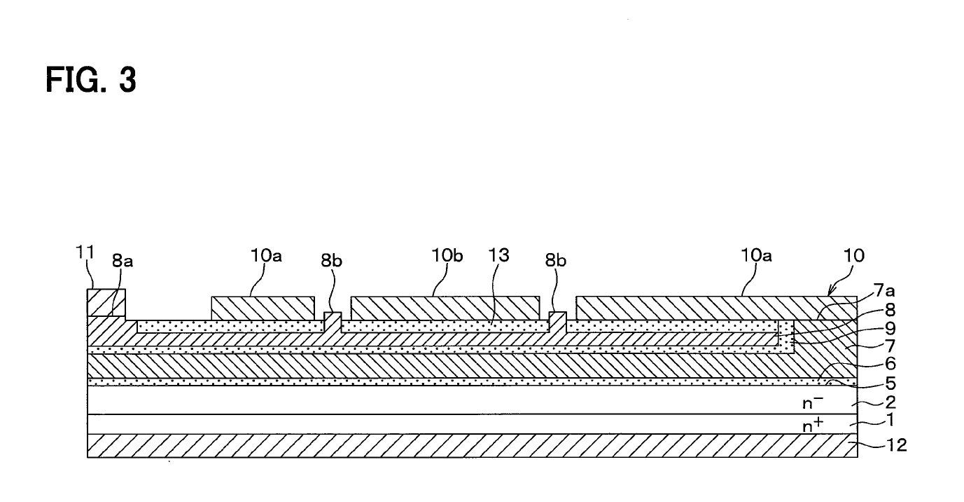

As shown in FIG. 3, the trench 5 is continuously connected between the main cell region Rm and the sense cell region Rs. The shield electrode 7 and the gate electrode layer 8, which are buried in the trench 5, are also continuously connected so as to reach both of the main cell region Rm and the sense cell region Rs.

Further, at one end of the trench 5 in the longitudinal direction, specifically, at a right end portion of the paper sheet in FIG. 3, the shield electrode 7 extends to an outside of the main cell region Rm from the gate electrode layer 8, that is, to a side of the main cell region Rm away from the sense cell region Rs. The shield electrode 7 is exposed from a surface of the channel p-type layer 3 as a shield liner 7a.

Similarly, at the other end of the trench 5 in the longitudinal direction, specifically, at a left end portion of the paper sheet in FIG. 3, the gate electrode layer 8 extends to an outside of the main cell region Rm from the shield electrode 7, that is, to a side of the main cell region Rm away from the sense cell region Rs. The gate electrode layer 8 is exposed from the surface of the channel p-type layer 3 as a gate liner 8a.

In the present embodiment, as shown in FIG. 3 and FIG. 4, the gate electrode layer 8 include protrusion portions 8b. The protrusion portion 8b protrudes above the n⁺-type impurity region 4. The protrusion portion 8b has the same configuration as that of the gate liner 8a, and is formed between the main cell region Rm and the sense cell region Rs. The protrusion portion 8b is used as a mask when the channel p-type layer 3 is formed by ion implantation, and is formed at a position corresponding to a position between the main channel layer 3a and the sense channel layer 3b. In other words, the protrusion portions 8b are formed on both sides of the sense cell region Rs. The gate insulating film 6 and an interlayer insulating film 13 to be described later are disposed between the protrusion portions 8b and the channel p-type layer 3 located below the protrusion portions 8b, and the protrusion portions 8b and the gate electrode layer 8 are insulated from the channel p-type layer 3.

The interlayer insulating film 13 made of an oxide film or the like is formed so as to cover the gate electrode layer 8, and an upper electrode 10 corresponding to a source electrode and a gate electrode 11 are formed on the interlayer insulating film 13. The upper electrodes 10 are electrically connected to the n⁺-type impurity regions 4 and the channel p-type layer 3 through portions where the interlayer insulating film 13 is not formed, for example, contact holes. The gate electrode 11 is also electrically connected to the gate electrode layer 8 through the gate liner 8a through the portions where the interlayer insulating film 13 is not formed, for example, the contact holes.

The upper electrode 10 is divided into a main electrode 10a formed in the main cell region Rm and a sense electrode 10b formed in the sense cell region Rs, and those electrodes 10a and 10b are separated from each other by a predetermined distance. The main electrode 10a is formed over almost the entire main cell region Rm, and is formed in a rectangular frame shape which is partially cut out. The sense electrode 10b has a rectangular shape, and is disposed so as to be surrounded by the main electrode 10a. One side of the sense electrode 10b is connected to a lead wiring 10c, and is led out to the outside of the main cell region Rm through a cut out provided in the main electrode 10a.

Further, a lower electrode 12 corresponding to a drain electrode is formed on a surface of the n⁺-type semiconductor substrate 1 opposite to the n⁻-type drift layer 2. The configuration described above configures a basic structure of the vertical MOSFET. As shown in FIG. 2, the main cell region Rm and the sense cell region Rs are configured by collecting multiple cells of the vertical MOSFET.

As described above, the semiconductor device having the vertical MOSFETs is formed. Next, a method of manufacturing the semiconductor device according to the present embodiment will be described. However, in the manufacturing method of the semiconductor device according to the present embodiment, portions different from the conventional one will be described, and the same portion as the conventional one will be described in a simplified manner.

First, the semiconductor substrate 1 is prepared, and the n⁻-type drift layer 2 is epitaxially grown on the surface of the semiconductor substrate 1. Next, a mask (not shown) having openings at regions where the trenches 5 are to be formed is placed, and the trenches 5 are provided by etching using the mask. Subsequently, after the gate insulating film 6 is formed on the surface of the n⁻-type drift layer 2 including the inner wall surfaces of the trenches 5 by thermal oxidation or the like, polysilicon is stacked and then etched back to be left only at the bottom portions of the trenches 5 and one end portions of the trenches 5, thereby forming the shield electrode 7.

Further, after the insulating film 9 has been formed, polysilicon is stacked again, a mask covering regions where the protrusion portions 8b are to be formed is placed on the polysilicon, and etching back is performed to form the gate electrode layer 8 in the trench 5 and to form the protrusion portions 8b. As a result, the trench gate structure is formed and the protrusion portions 8b are formed.

Thereafter, a p-type impurity is ion-implanted to form the channel p-type layer 3. At this time, since the protrusion portions 8b are formed by parts of the gate electrode layer 8, ion implantation of the p-type impurity is blocked by the protrusion portions 8b serving as a mask, and the channel p-type layer 3 is not formed in the portion where the protrusion portions 8b are formed. As a result, the main channel layer 3a can be formed in the main cell region Rm, the sense channel layer 3b can be formed in the sense cell region Rs, and the main channel layer 3a and the sense channel layer 3b can be separated from each other.

After a mask having openings at regions where the n⁺-type impurity regions 4 are to be formed has been placed, n-type impurities are ion-implanted to form the n⁺-type impurity regions 4. Thereafter, the process of forming the interlayer insulating film 13, the process of forming the contact hole, the process of forming the upper electrode 10 and the gate liner 8a, and the process of forming the lower electrode 12 are performed to complete the semiconductor device having the vertical MOSFET according to the present embodiment.

According to the semiconductor device configured as described above, the following effects can be obtained.

First, as described above, the trenches 5 are continuously connected so as to reach both of the main cell region Rm and the sense cell region Rs, and the shield electrodes 7 and the gate electrode layers 8 are continuously formed so as to reach both of the main cell region Rm and the sense cell region Rs.

Thus, there is no need to contact the shield electrode 7 between the main cell region Rm and the sense cell region Rs, so that the main cell region Rm and the sense cell region Rs can be brought closer to each other. Accordingly, the current can be restricted from spreading and flowing between the main cell region Rm and the sense cell region Rs, and the current can flow uniformly in the vertical direction in the sense cell region Rs as in the main cell region Rm. Therefore, the accuracy of the sense cell can be improved.

Further, in the semiconductor device of the present embodiment, parts of the gate electrode layer 8 are formed as the protrusion portions 8b, as a result of which the channel p-type layer 3 is divided into the main channel layer 3a and the sense channel layer 3b between the main cell region Rm and the sense cell region Rs. If the protrusion portions 8b are not provided, there is a need to perform ion implantation after forming a mask (not shown) covering a space between the main channel layer 3a and the sense channel layer 3b at the time of ion implantation of the p-type impurity in forming the channel p-type layer 3. However, with the formation of the protrusion portions 8b with parts of the gate electrode layer 8 as in the present embodiment, the protrusion portions 8b can be used as a mask, and there is no need to perform mask formation again. Thus, the process of manufacturing the semiconductor device can be simplified.

Further, since the protrusion portions 8b can be formed by a mask common to the gate liner 8a disposed outside the main cell region Rm, there is no need to prepare a mask only for forming the protrusion portions 8b, and the manufacturing process can be made common. Thus, the manufacturing cost can be reduced.

Further, the sense cell region Rs is surrounded by the main cell region Rm. Thus, as compared with the case where the main cell region Rm is not provided around the sense cell region Rs, the operation of the sense cell region Rs can be made more uniform, and a higher accuracy of the sense cell can be achieved.

### Other Embodiments

Although the present disclosure has been described in accordance with the embodiment described above, the present disclosure is not limited to the embodiment described above, and encompasses various modifications and variations within the scope of equivalents. In addition, various combinations and configurations, as well as other combinations and configurations that include only one element, more, or less, are within the scope and spirit of the present disclosure.

For example, in the embodiment described above, the protrusion portions 8b are provided in parts of the gate electrode layer 8, and serves as a mask for separating the main channel layer 3a and the sense channel layer 3b from each other at the time of ion implantation. On the other hand, instead of providing the protrusion portions 8b in parts of the gate electrode layer 8, a mask may be formed as a step separate from the step of forming the gate electrode layer 8, and the main channel layer 3a and the sense channel layer 3b may be separated from each other at the time of ion implantation using the mask.

In the manufacturing method described above, since the step of forming the main channel layer 3a, the sense channel layer 3b, and the n⁺-type impurity regions 4 can be performed as a different step from the step of forming the gate electrode layer 8, those elements may be formed prior to forming the trenches 5.

In the embodiment described above, an example in which the impurity region of a high concentration is formed by the semiconductor substrate 1 and the n⁻-type drift layer 2 is epitaxially grown on the impurity region is shown. This is merely an example of the case where a high concentration impurity region is formed on the opposite side of the channel p-type layer 3 across the drift layer, and the impurity region of a high concentration may be formed by forming the drift layer with the semiconductor substrate and performing ion implantation or the like on a rear surface side of the semiconductor substrate.

In the above embodiment, the main cell region Rm has a rectangular frame shape so as to surround the sense cell region Rs, but the main cell region Rm may have a frame shape other than the rectangular frame shape, or may have a configuration in which the sense cell region Rs is not surrounded by the main cell region Rm.

Further, an interval between the cell provided in the main cell region Rm and the cell provided in the sense cell region Rs is set to be wider than an interval between the cells provided in the same region. Specifically, an interval between the trench gate structure formed in the main cell region Rm and the trench gate structure formed in the sense cell region Rs is set to be wider than an interval between the trench gate structures formed in the main cell regions Rm and an interval between the trench gate structures formed in the sense cell regions Rs. Also in the above interval, as the distance increases, a current flows in the horizontal direction from the sense cell region Rs toward the main cell region Rm side, and the current flowing in the vertical direction in the sense cell region Rs becomes not uniform. As a result, it is preferable to narrow the interval as much as possible. On the other hand, in the MOSFET of the structure described above, in an array direction perpendicular to the longitudinal direction of the trench gate structure, an interval between the cell provided in the main cell region Rm and the cell formed in the sense cell region Rs can be narrowed. Accordingly, the current flowing in the horizontal direction from the sense cell region Rs toward the main cell region Rm can be further restricted, the current can flow in the vertical direction uniform in the sense cell region Rs, and the accuracy of the sense cell can be further improved.

In the embodiment described above, the MOSFET of the n-channel type trench gate structure in which the first conductivity type is n-type and the second conductivity type is p-type has been described as an example of the semiconductor switching element. However, this is merely an example, and a semiconductor switching element of another structure, for example, a MOSFET of a trench gate structure of a p-channel type in which the conductivity type of each component is inverted with respect to the n-channel type may be used. In addition to the MOSFET, the present disclosure can be applied to an IGBT having a similar construction. In the IGBT case, except that the conductive type of the semiconductor substrate 1 is changed from the n-type to the p-type, the configuration is the same as the vertical MOSFET described in the embodiment described above.

What is claimed is:

1. A semiconductor device comprising a main cell region and a sense cell region each including a semiconductor switching element, and configured to detect a current flowing through the semiconductor switching element in the main cell region by the semiconductor switching element in the sense cell region, the semiconductor switching element including:
a drift layer of a first conductivity type;
a channel layer of a second conductivity type disposed on the drift layer;
a first impurity region of a first conductivity type disposed in a surface layer portion of the channel layer and having an impurity concentration higher than an impurity concentration of the drift layer;
a trench gate structure in which a shield electrode and a gate electrode layer are stacked as a two-layer structure through a gate insulating film within a trench that reaches the drift layer from the first impurity region through the channel layer and extends in one direction as a longitudinal direction;
a second impurity region of the first or second conductivity type disposed on an opposite side to the channel layer across the drift layer and has an impurity concentration higher than the impurity concentration of the drift layer;
an upper electrode electrically connected to the first impurity region and the channel layer and electrically connected to the shield electrode;
a gate liner electrically connected to the gate electrode layer; and
a lower electrode electrically connected to the second impurity region, wherein
the trench is continuously connected to reach the main cell region and the sense cell region, and the shield electrode and the gate electrode layer are continuously connected to reach the main cell region and the sense cell region within the trench,
the shield electrode extends to a side of the main cell region away from the sense cell region on one end side of the trench in the longitudinal direction to be electrically connected to the upper electrode, and
the gate electrode layer extends to a side of the main cell region away from the sense cell region on the other end side of the trench in the longitudinal direction to be electrically connected to the gate liner.

2. The semiconductor device according to claim 1, wherein
the channel layer includes a main channel layer disposed in the main cell region and a sense channel layer disposed in the sense cell region, and the main channel layer and the sense channel layer are separated from each other, and
the gate electrode layer includes a protrusion portion that protrudes above the first impurity region at a position corresponding to a position between the main channel layer and the sense channel layer.

3. The semiconductor device according to claim 1, wherein
the upper electrode includes a main electrode of the semiconductor switching element disposed in the main cell region and a sense electrode of the semiconductor switching element disposed in the sense cell region, and
the main cell region has a frame shape that is partially cut out, the sense cell region is disposed in the main cell region, and the sense electrode is connected to a lead wiring that is led out from a portion of the main cell region that is partially cut out to an outside of the main cell region.
